(19) United States
(12) Patent Application Publication
(10) Pub. No.: US 2006/0134930 A1
(43) Pub. Date: Jun. 22, 2006

(54) Method for forming a metal contact in a semiconductor device having a barrier metal layer formed by homogeneous deposition

(75) Inventor: Dong-Ki Jeon, Seoul (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/316,632

(22) Filed: Dec. 20, 2005

(30) Foreign Application Priority Data
Dec. 22, 2004 (KR) 10-2004-0110619

(51) Int. Cl. H01L 21/4763; H01L 21/26

(52) U.S. Cl. 438/798; 438/637

(57) ABSTRACT

Low resistance, high performance, and a longer lifetime of a semiconductor device may be achieved when a metal contact is formed in a semiconductor device by a method including: forming a lower metal layer on a semiconductor substrate; forming an interlayer insulating layer having a via hole on the lower metal layer; forming a first metal layer on the interlayer insulating layer and an interior of the via hole; forming a second metal layer on the first metal layer by a homogeneous deposition method in which deposition, densification, and plasma treatment are simultaneously performed; and forming an upper metal layer on the second metal layer so as to fill the via hole.

### CROSS-REFERENCE TO RELATED APPLICATION

This application claims priority to and the benefit of Korean Patent Application 10-2004-0110619, filed in the Korean Intellectual Property Office on Dec. 22, 2004, the entire contents of which are incorporated herein by reference.

### BACKGROUND OF THE INVENTION

(a) Field of the Invention

The present invention relates to a method for forming a metal contact in a semiconductor device. More particularly, the present invention relates to a method for forming a metal contact in a semiconductor device having a barrier metal layer.

(b) Description of the Related Art

According to a typical method for forming a metal contact in a semiconductor device, a first barrier metal layer made of titanium (Ti) and a second barrier metal layer made of titanium nitride (TiN) are sequentially formed in a via hole to a lower metal layer, and then a metal is deposited on the second barrier metal layer to fill the via hole.

In order to uniformly form the second barrier metal layer in the via hole, a CVD TiN process is widely used, in which the titanium nitride (TiN) is formed by chemical vapor deposition (CVD). The CVD TiN process includes deposition of a precursor organometallic compound by thermal decomposition, densification of the deposited thin film, and plasma treatment thereof in order to remove impurities. Such a method of deposition according to two processes of deposition and densification is usually called a heterogeneous deposition method.

When depositing a titanium nitride layer by the heterogeneous deposition method, plasma treatment may or may not be applied. A titanium nitride layer that is not plasma treated has an amorphous structure different from a crystalline structure of a typical metal, and it may have as high a resistance as a non-conductive material. Even if the titanium nitride layer is plasma treated, the effect of the plasma treatment does not reach below a certain depth, regardless of how long the plasma treatment is applied. Therefore, the plasma treatment may not sufficiently reduce the resistance.

The above information disclosed in this Background section is only for enhancement of understanding of the background of the invention, and therefore it may contain information that does not form prior art or other information that is already known in this or any other country to a person of ordinary skill in the art.

### SUMMARY OF THE INVENTION

The present invention has been made in an effort to provide a method for forming a metal contact in a semiconductor device having the advantage of providing a barrier metal layer having low resistance.

An exemplary method for forming a metal contact in a semiconductor device according to an embodiment of the present invention may include: forming a lower metal layer on a semiconductor substrate; forming an insulating layer having a via hole on the lower metal layer; forming a first metal layer on the insulating layer and an interior of the via hole; forming a second metal layer on the first metal layer by a homogeneous deposition method in which deposition, densification, and plasma treatment are simultaneously performed; and forming an upper metal layer on the second metal layer so as to fill the via hole.

After forming the insulating layer, the lower metal layer may be sputter-etched at a portion thereof exposed through the via hole.

The second metal layer may be formed by a chemical vapor deposition (CVD) method, and may comprise a TiN layer.

The second metal layer may have a crystalline structure.

The second metal layer may be deposited at a temperature in a range of from room temperature to 500° C.

Forming the upper metal layer may include forming a tungsten layer on the insulating layer so as to fill the via hole, and processing the tungsten layer by an etch-back method or chemical mechanical polishing to remove the tungsten layer from outside the via hole.

According to such a method, high performance of a semiconductor device may be achieved by lowering the contact resistance, and a longer lifetime of a semiconductor device may be achieved by increasing the effect of impurity removal from a contact structure.

### BRIEF DESCRIPTION OF THE DRAWINGS

FIG. 1 to FIG. 5 are cross-sectional views for illustrating a method for forming a metal contact in a semiconductor device according to an exemplary embodiment of the present invention.

FIG. 6 is a cross-sectional view for a comparison of second barrier metal layers formed by a conventional method and a method according to an exemplary embodiment of the present invention.

### DETAILED DESCRIPTION OF THE EMBODIMENTS

An embodiment of the present invention will hereinafter be described in detail with reference to the accompanying drawings.

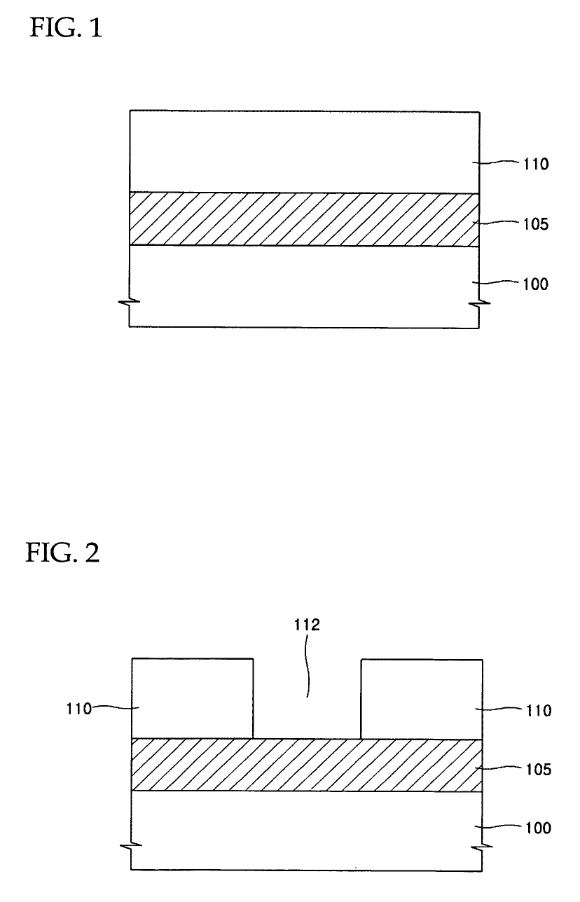

FIG. 1 to FIG. 5 are cross-sectional views for illustrating a method for forming a metal contact in a semiconductor device according to an exemplary embodiment of the present invention.

As shown in FIG. 1, a lower metal layer 105 is formed on or over a semiconductor substrate 100, e.g., a single-crystal silicon substrate that may have one or more epitaxial layers of silicon or silicon-germanium thereon and one or more dielectric or insulator layers thereover. The lower metal layer 105 generally comprises aluminum, aluminum-copper alloy, titanium, titanium nitride, tungsten, titanium-tungsten alloy or a stacked or multi-layered composite thereof (e.g., a titanium/titanium nitride/aluminum-copper alloy containing 0.5-2 wt. % copper/titanium/titanium nitride structure). FIG. 1 illustrates that the lower metal layer 105 is directly formed on the semiconductor substrate 100 in the present exemplary embodiment; however, the present invention is not limited thereto. Below the lower metal layer 105, other layers such as an insulating layer may be employed or included on the semiconductor substrate 100. An insulating layer 110 is formed on the lower metal layer 105. When such an insulating layer is located between two adjacent metal layers, it may be considered to be an “interlayer” insulating layer. The insulating layer 110 may comprise an oxide layer such as silicon dioxide (which may be doped with fluorine or one or more other dopants such as boron and phosphorous), silicon-rich oxide, a stacked or laminated multi-layer composite thereof, etc.

Referring to FIG. 2, the insulating layer 110 is patterned to form a via hole 112, exposing a part of the lower metal layer 105. Subsequently, sputter etching may be performed so as to remove a natural oxide layer on the part of the lower metal layer 105 exposed in the via hole 112. The entrance of the via hole 112 may be slightly enlarged by the sputter etching, and thus a subsequently formed barrier metal layer and upper metal layer may fill the via hole 112 more easily, while minimizing a shadow effect due to an overhang at the top of the via hole. The sputter etching may be performed in an apparatus for forming a liner or barrier metal layer in the via hole.

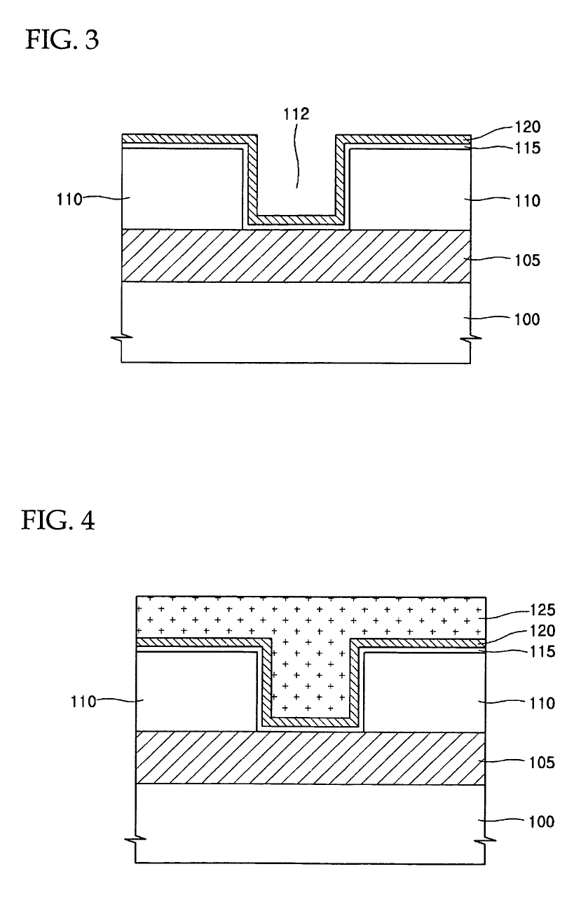

Referring to FIG. 3, a first metal layer (or liner) 115 is formed on the patterned insulating layer 1 10 and an interior of the via hole 112 (e.g., on an interior surface, such as a sidewall or exposed part of the metal layer at the bottom). The first metal layer 115 may comprise a titanium (Ti) layer. The first metal layer 115 also enables ohmic contact between the lower metal layer 105 and an upper metal layer that will be formed later, and may improve adhesion of the second metal layer to the underlying metal line 105 and/or the dielectric material of the insulating layer 110.

Subsequently, a second (or barrier) metal layer 120 is formed on the first metal layer 115. The second metal layer 120 is also formed in the interior of the via hole 112. The second barrier metal layer 120 may comprise a titanium nitride (TiN) layer. The second barrier metal layer 120 is deposited conformally on sidewalls and the bottom of the via hole 112, and it generally blocks an attack of fluorine (F) that may be generated during a subsequent deposition of the upper metal layer on the underlying first barrier layer, while maintaining the ohmic contact.

The second metal layer 120 may be formed by a CVD TiN deposition method, and in more detail, by a homogeneous deposition method in which deposition, densification, and plasma treatment are performed at the same time. That is, the second metal layer 120 according to an exemplary embodiment of the present invention is formed not by a heterogeneous deposition method in which deposition, densification, and plasma treatment of an organometallic compound as a precursor are sequentially processed, but rather by simultaneous thermal decomposition, densification, and plasma treatment (e.g., to enable and/or assist impurity removal) of the organometallic compound. Suitable organometallic compounds include those conventionally used as TiN precursors, such as those of the formula Ti(NR₂)₄, where R is an alkyl group such as methyl, ethyl, propyl, iso- or t-butyl, etc. The plasma power may be maintained in a range of 100 w to 2 kw while forming the second barrier metal layer 120. The second barrier metal layer 120 may be deposited at a low temperature range of room temperature to 500 ° C., or at a higher temperature.

By such a homogeneous deposition method, the second (barrier) metal layer 120 according to an exemplary embodiment of the present invention may have a crystalline or polycrystalline structure, preferably having a thickness of 70Å or more. The second metal layer 120 according to an exemplary embodiment of the present invention may have a low resistivity of 500 μΩ-cm or less, regardless of its thickness. The second barrier metal layer 120 according to an exemplary embodiment of the present invention may achieve a low content of impurities of less than or equal to 5 atomic %, regardless of its thickness.

With the second barrier metal layer 120 according to an exemplary embodiment of the present invention, impurity removal efficiency due to the plasma may be increased, and thus resistivity may be reduced by maximizing the impurity removal efficiency. In particular, it is conventionally difficult to deposit a second (barrier) metal layer of a desired resistivity to more than a predetermined thickness by CVD since the plasma-reaching depth is limited.

Referring to FIG. 4, an upper metal layer 125 is formed on the second metal layer 120 to sufficiently fill the via hole 112. The upper metal layer 125 may comprise a tungsten layer. The upper metal layer 125 is also formed on the second metal layer 120 above the insulating layer 110.

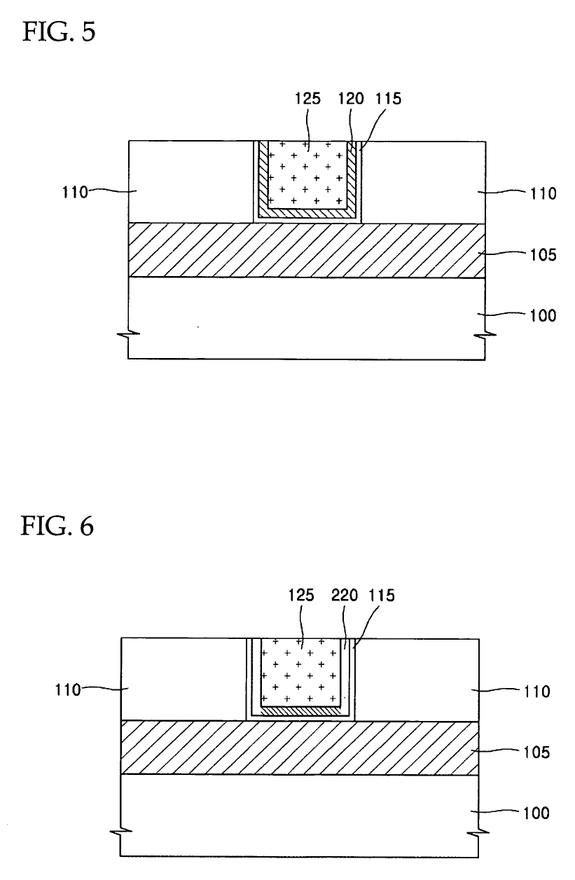

Referring to FIG. 5, the upper metal layer 125 is etched back or polished by chemical mechanical polishing (CMP). Consequently, the upper metal layer 125 filling the via hole 112 is in the form of a metal plug. At this time, the first metal layer 115 and the second metal layer 120 are also etched back or polished such that they are removed from outside the via hole 112.

Hereinafter, the second (barrier) metal layer according to an exemplary embodiment of the present invention is compared with a conventional one with reference to FIG. 5 and FIG. 6, which are cross-sectional views for the comparison (i.e., of second [barrier] metal layers formed by a conventional method and a method according to an exemplary embodiment of the present invention).

In FIG. 5 and FIG. 6, like reference numerals designate like elements. When the second (barrier) metal layer 220 is formed by a heterogeneous deposition method, the second (barrier) metal layer 220 is densified at the bottom of the via hole but not at sidewalls thereof (refer to the hatched portion in FIG. 6) due to the directionality of the plasma. Therefore, when an upper metal layer (i.e., a tungsten plug) is subsequently formed, the tungsten keyhole size is enlarged.

However, when the second (barrier) metal layer 120 is deposited by the homogeneous deposition method, the second (barrier) metal layer 120 is densified at both the bottom and the sidewalls of the via hole 112 (refer to the hatched portion in FIG. 5) to a sufficient level. Therefore, when an upper metal layer (i.e., a tungsten plug) is subsequently formed, the tungsten keyhole size may be substantially decreased.

As described above, the barrier metal layer according to an exemplary embodiment of the present invention is simultaneously thermally decomposed and plasma treated. Therefore, deposition at a low temperature may be enabled, impurity removal efficiency due to the plasma may be increased, and thus resistivity may be reduced.

In addition, according to an embodiment of the present invention, performance (e.g., operational speed) of a device may be enhanced since resistivity of the second barrier metal layer can be decreased, and the lifetime of the semiconductor device may be increased since more efficient removal of impurities that may have an adverse influence on semiconductor device characteristics are removed more efficiently. Consequently, a barrier metal layer formed by homogeneous deposition in a metal contact in a semiconductor device may enhance device characteristics and reduce failures.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method for forming a metal line in a semiconductor device, comprising:
forming a first metal layer on an interior of a via hole in an insulating layer, the via hole exposing a lower metal layer;
forming a second metal layer on the first metal layer by simultaneous deposition, densification, and plasma treatment; and
forming an upper metal layer on the second metal layer so as to fill the via hole.

2. The method of claim 1, further comprising, before forming the first metal layer, sputter etching the exposed lower metal layer.

3. The method of claim 1, wherein forming the second metal layer comprises chemical vapor deposition (CVD).

4. The method of claim 1, wherein the second metal layer comprises a TiN layer.

5. The method of claim 1, wherein the second metal layer has a crystalline or polycrystalline structure.

6. The method of claim 1, wherein forming the second metal layer comprises depositing the second metal layer at a temperature in a range of from room temperature to 500° C.

7. The method of claim 1, further comprising forming the lower metal layer on the semiconductor substrate.

8. The method of claim 7, further comprising forming the insulating layer on the lower metal layer.

9. The method of claim 8, further comprising forming the via hole in the insulating layer.

10. The method of claim 1, wherein forming the upper metal layer comprises:
forming a tungsten layer on the insulating layer so as to fill the via hole; and
processing the tungsten layer by an etch-back method or chemical mechanical polishing to remove the tungsten layer from outside the via hole.

11. The method of claim 2, wherein:
forming the second metal layer comprises chemical vapor deposition (CVD) at a temperature in a range of from room temperature to 500° C.;
the second metal layer comprises a TiN layer;
the second metal layer has a crystalline or polycrystalline structure; and
forming the upper metal layer comprises forming a tungsten layer on the interlayer insulating layer so as to fill the via hole, and processing the tungsten layer by an etch-back method or chemical mechanical polishing to remove the tungsten layer from outside the via hole.
